(19) United States
(12) Patent Application Publication
(10) Pub. No.: US 2007/0138496 A1
(43) Pub. Date: Jun. 21, 2007

(54) Light emitting diode with plural emission openings and backlight module with same

(75) Inventors: San-Dan Zhao, Shenzhen (CN); Liao-Liao Zhu, Shenzhen (CN); Zheng-Xiao Chen, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/638,808

(22) Filed: Dec. 14, 2006

(30) Foreign Application Priority Data
Dec. 16, 2005 (TW) 94144853

(51) Int. Cl. H01L 33/00

(52) U.S. Cl. 257/98

(57) ABSTRACT

An exemplary light emitting diode (LED) (21) includes a light emitting crystal grain (211) and a case frame (212). The case frame includes a substrate (2121) and a plurality of sidewalls (2122) extending from the substrate. The sidewalls cooperatively define a first opening (2124) therebetween opposite to the substrate. One of the sidewalls has a second opening (2125) defined therein. The light emitting crystal grain is located in the case frame. Light beams emitting from the first opening are used to illuminate a display panel. Light beams emitting from the second openings are used to meet other special demands. Therefore, the light emitting diode can meet diversified illumination demands of various modern electronic devices.

### FIELD OF THE INVENTION

The present invention relates to light emitting diodes (LEDs) and their use in backlight modules, including backlight modules that are applied in liquid crystal displays.

### GENERAL BACKGROUND

A typical liquid crystal display is capable of displaying a clear and sharp image through thousands or even millions of pixels that make up the complete image. The liquid crystal display has thus been applied to various electronic equipment in which messages or pictures need to be displayed, such as mobile phones and notebook computers. However, liquid crystal in the liquid crystal display does not itself emit light. Rather, the liquid crystal has to be lit up by a light source so as to clearly and sharply display text and images. The light source may be ambient light, or a backlight module attached to the liquid crystal display.

Referring to FIG. 5, a typical backlight module is shown. The backlight module 1 includes a reflective plate 12, a light guide plate 13, a diffusing plate 14, and a light enhancement film 15, which are stacked in that order from bottom to top. The backlight module 1 further includes a light emitting diode (LED) 11 located adjacent to a light incident surface 131 of the light guide plate 13.

The light guide plate 13 further includes a light emitting surface 132 perpendicularly connecting with the light incident surface 131, and a bottom surface 133 opposite to the light emitting surface 132. The reflective plate 12 is disposed adjacent to the bottom surface 133 of the light guide plate 13. The diffusing plate 14 is disposed adjacent to the light emitting surface 132 of the light guide plate 13.

Referring also to FIGS. 6 and 7, the LED 11 includes a light emitting crystal grain 111, a case frame 112, and transparent resin 113. The case frame 112 includes a metal substrate 1121, and four sidewalls 1122 substantially perpendicularly extending from the metal substrate 1121. Top ends of the sidewalls 1122 commonly define a bezel surface 1123 of the case frame 112. A rectangular opening 1124 is defined inside the bezel surface 1123. The metal substrate 1121 includes a first metal plate 1121a functioning as a positive electrode, a second metal plate 1121b functioning as a negative electrode, and an insulating resin 1126 jointed between the first and second metal plates 1121a, 1121b. The light emitting crystal grain 111 is adhered on the first metal plate 1121a by resin binder, and is electrically connected to the first and second metal plates 1121a, 1121b by wires 1127, respectively. The transparent resin 113 is filled into the case frame 112 through the opening 1124, so as to seal the light emitting crystal grain 111.

The LED 11 only emits light from the opening 1124 thereof. That is, the LED 11 only emits light in a single angular range. This does not necessarily meet the demands of modern electronic devices. For example, a typical mobile phone with a backlight module needs to not only illuminate a display panel, but also illuminate control buttons. The LED 11 is unsuited for this kind of application.

Therefore, what is needed is a new LED that can overcome the above-described problems. What is also needed is a backlight module employing the LED.

### SUMMARY

In one preferred embodiment, a light emitting diode includes a light emitting crystal grain and a case frame. The case frame includes a substrate and a plurality of sidewalls extending from the substrate. The sidewalls cooperatively define a first opening therebetween opposite to the substrate. One of the sidewalls has a second opening defined therein. The light emitting crystal grain is located in the case frame.

Other advantages and novel features will become more apparent from the following detailed description when taken in conjunction with the accompanying drawings. In the drawings, all the views are schematic.

### BRIEF DESCRIPTION OF THE DRAWINGS

FIG. 1 is an exploded, side view of a backlight module according to an exemplary embodiment of the present invention, the backlight module including a light emitting diode.

FIG. 2 is an enlarged, front, isometric view of the light emitting diode of FIG. 1.

FIG. 3 is an enlarged, back, isometric of the light emitting diode of FIG. 1.

FIG. 4 is an enlarged, cross-sectional view taken along line IV-IV of FIG. 2.

FIG. 5 is an exploded, side view of a conventional backlight module, the backlight module including a light emitting diode.

FIG. 6 is an enlarged, isometric view of the light emitting diode of FIG. 5.

FIG. 7 is an enlarged, cross-sectional view taken along line VII-VII of FIG. 6.

### DETAILED DESCRIPTION OF PREFERRED EMBODIMENTS

Referring to FIG. 1, a backlight module according to a first embodiment of the present invention is shown. The backlight module 2 includes a reflective plate 22, a light guide plate 23, a diffusing plate 24, and a light enhancement film 25, stacked in that order from bottom to top. The backlight module 2 further includes a light emitting diode (LED) 21 located adjacent to a light incident surface 231 of the light guide plate 23.

The light guide plate 23 further includes a light emitting surface 232 perpendicularly connecting with the light incident surface 231, and a bottom surface 233 opposite to the light emitting surface 232. The reflective plate 22 is disposed adjacent to the bottom surface 233 of the light guide plate 23. The diffusing plate 24 is disposed adjacent to the light emitting surface 232 of the light guide plate 23.

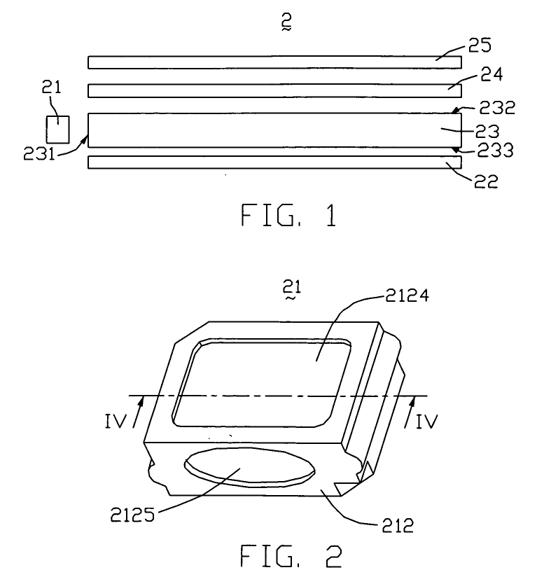

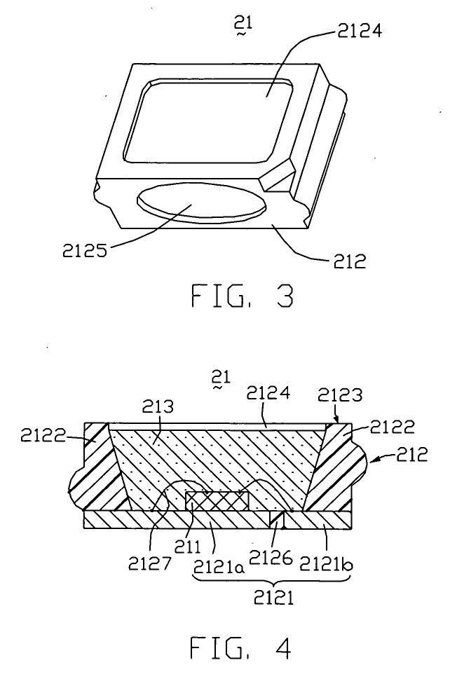

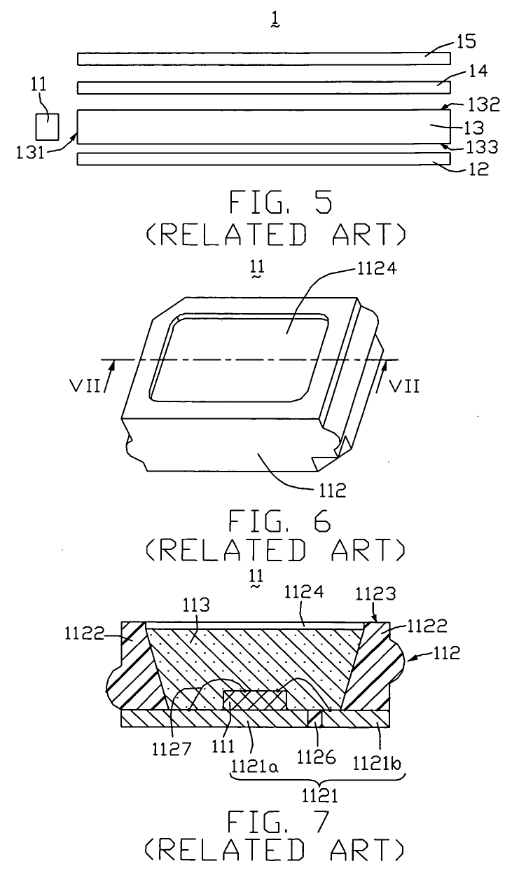

Referring to FIGS. 2, 3 and 4, the LED 21 includes a light emitting crystal grain 211, a case frame 212, and transparent resin 213. The case frame 212 includes a metal substrate 2121, and four sidewalls 2122 substantially perpendicularly extending from the metal substrate 2121. Top ends of the sidewalls 2122 commonly define a bezel surface 2123 of the case frame 212. A first opening 2124 defined inside the bezel surface 2123. Two second openings 2125 are defined in two opposite of the sidewalls 2122 respectively. In the illustrated embodiment, the first opening 2124 is rectangular, and the second openings 2125 are elliptical. The metal substrate 2121 includes a first metal plate 2121a functioning as a positive electrode, a second metal plate 2121b functioning as a negative electrode, and insulating resin 2126 jointed between the first and second metal plates 2121a, 2121b. The light emitting crystal grain 211 is adhered on the first metal plate 2121a by resin binder, and is electrically connected to the first and second metal plates 2121a, 2121b by wires 2127, respectively. The transparent resin 113 is filled into the case frame 212 through the first opening 2124, so as to seal the light emitting crystal grain 211.

When the backlight module 2 is assembled, the bezel surface 2123 of the LED 21 is disposed adjacent to the light incident surface 231 of the light guide plate 23, whereby the first opening 2124 faces the light incident surface 231. Light beams emitting from the first opening 2124 enter the light guide plate 23 through the light incident surface 231, and finally emit from the light emitting surface 232. In a typical application, these light beams are used to illuminate a display panel (not shown), such as a display panel of a mobile phone. Light beams emitting from the second openings 2125 are used for other illumination requirements. For example, these light beams can be used to illuminate control buttons of a mobile phone. In general, the backlight module 2 having the LED 21 can meet diversified illumination demands of various modern electronic devices.

In summary of one exemplary application, when the backlight module 2 is used in a mobile phone, light beams emitting from the first opening 2124 are used to illuminate a display panel of the mobile phone, and light beams emitting from the second openings 2125 are used to illuminate control buttons of the mobile phone.

Further or alternative embodiments may include the following. The second openings 2125 can be defined at different sidewalls 2122 of the LED 21, as required by a particular application. The first opening 2124 can have any of various suitable shapes, such as round, elliptical, or triangular. The second openings 2125 can have any of various suitable shapes, such as rectangular, round, or triangular. There can be only a single second opening 2125, provided in a selected one of the sidewalls 2122.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A light emitting diode (LED) comprising:
a light emitting crystal grain; and
a case frame comprising a substrate and a plurality of sidewalls extending from the substrate, the sidewalls cooperatively defining a first opening therebetween opposite to the substrate, one of the sidewalls having a second opening defined therein;
wherein the light emitting crystal grain is located in the case frame.

2. The LED as claimed in claim 1, wherein each of the first and second openings is rectangular, round, elliptical, or triangular.

3. The LED as claimed in claim 1, wherein the substrate is a metal substrate.

4. The LED as claimed in claim 3, wherein the metal substrate comprises a first metal plate configured to function as a positive electrode and a second metal plate configured to function as a negative electrode.

5. The LED as claimed in claim 4, wherein the first and the second metal plates are jointed via insulating resin therebetween.

6. The LED as claimed in claim 4, wherein the light emitting crystal grain is located on the first metal plate.

7. The LED as claimed in claim 4, wherein the light emitting crystal grain is electrically connected to the first and second metal plates via wires.

8. The LED as claimed in claim 1, wherein another one of the sidewalls has a third opening defined therein.

9. A backlight module comprising:
a light guide plate; and
a light emitting diode (LED) located adjacent to the light guide plate, the LED comprising:
a light emitting crystal grain; and
a case frame comprising a substrate and a plurality of sidewalls extending from the substrate, the sidewalls cooperatively defining a first opening therebetween opposite to the substrate, one of the sidewalls having a second opening defined therein;
wherein the light emitting crystal grain is located in the case frame.

10. The backlight module as claimed in claim 9, wherein each of the first and second openings is rectangular, round, triangular, or elliptical.

11. The backlight module as claimed in claim 9, wherein the substrate is a metal substrate.

12. The backlight module as claimed in claim 11, wherein the metal substrate comprises a first metal plate configured to function as a positive electrode and a second metal plate configured to function as a negative electrode.

13. The backlight module as claimed in claim 12, wherein the first and the second metal plates are jointed via insulating resin therebetween.

14. The backlight module as claimed in claim 12, wherein the light emitting crystal grain is located on the first metal plate.

15. The backlight module as claimed in claim 12, wherein the light emitting crystal grain is electrically connected to the first and second metal plates via wires.

16. The backlight module as claimed in claim 9, wherein another one of the sidewalls has a third opening defined therein.

17. The backlight module as claimed in claim 9, wherein the light guide plate comprises a light incident surface, a light emitting surface adjacent to the light incident surface, and a bottom surface opposite to the light emitting surface.

18. The backlight module as claimed in claim 17, wherein the first opening of the LED faces the light incident surface of the light guide plate

19. The backlight module as claimed in claim 17, further comprising a reflective plate located adjacent to the bottom surface of the light guide plate.

20. The backlight module as claimed in claim 17, further comprising a diffusing plate adjacent to the light emitting surface of the light guide plate, and a light enhancement film adjacent to the diffusing plate.
